(19) United States
(12) Patent Application Publication
(10) Pub. No.: US 2015/0260890 A1
(43) Pub. Date: Sep. 17, 2015

(54) OPTICAL PART, METHOD FOR MANUFACTURING OPTICAL PART, ELECTRONIC APPARATUS, AND MOVING OBJECT

(71) Applicant: SEIKO EPSON CORPORATION, Tokyo (JP)

(72) Inventors: Daiki FURUSATO, Ina-shi (JP); Shinichi URABAYASHI, Minowa-machi (JP); Naoki SAKAI, Minowa-machi (JP)

(21) Appl. No.: 14/657,175

(22) Filed: Mar. 13, 2015

(30) Foreign Application Priority Data
Mar. 13, 2014 (JP) 2014-049807

(51) Int. Cl. G02B 5/28; C23C 14/08; C23C 14/10; C23C 14/04

(52) U.S. Cl. CPC G02B 5/285; G02B 5/282; G02B 5/283; C23C 14/042; C23C 14/083; C23C 14/10

(57) ABSTRACT

An optical multilayer film filter as an optical part includes a glass substrate as an optical substrate and an inorganic thin film as a film provided on the glass substrate. The inorganic thin film has a first region and a second region that surrounds the first region and continuously extends from the first region, and the inorganic thin film in the second region has a thickness that increases with distance from an outer circumferential edge of the second region toward the boundary between the second region and the first region.

### BACKGROUND

1. Technical Field

The present invention relates to an optical part, a method for manufacturing the optical part, an electronic apparatus including the optical part, and a moving object including the optical part.

2. Related Art

When a film having a predetermined shape is formed on a substrate by using a mask, the film can be formed with the end portions of the film perpendicular to the surface of the substrate by minimizing the distance between the mask and the substrate, and the method is considered to be ideal because a film having a specified thickness can be produced over a wide region (see JP-A-10-145166, for example).

However, stress induced at the time of film formation is left (residual stress) in the film on the substrate, and the stress is abruptly released at the end portions of the film in the case where the end portions of the film are perpendicular to the surface of the substrate. As a result, the film undesirably tends to be separate from the surface of the substrate or otherwise has defects in portions in the vicinity of the end portions of the film. In the case of an optical part, in particular, an optical signal experiences irregular reflection or any other optical behavior in portions where the separation occurs (where defects are produced), possibly resulting in degradation in optical characteristics of the film.

### SUMMARY

An advantage of some aspects of the invention is to solve at least apart of the problems described above, and the invention can be implemented as the following aspects or application examples.

### APPLICATION EXAMPLE 1

An optical part according to this application example includes an optical substrate and a film provided on the substrate. The film has a first region and a second region that surrounds the first region and continuously extends from the first region, and the film in the second region has a thickness that increases with distance from an outer circumferential edge of the second region toward the boundary between the second region and the first region.

According to this application example, the film provided on the substrate has the second region in which the thickness of the film increases with distance from the outer circumferential edge of the second region toward the boundary between the second region and the first region. Since the second region allows residual stress, such as stress induced when the film is formed, to be gradually released, separation of the film or any other defect is unlikely to occur, whereby a region having a specified film thickness where intended optical performance (optical characteristics) is achieved can be provided.

### APPLICATION EXAMPLE 2

In the optical part according to the application example described above, it is preferable that a parallelism of an upper surface of the film in the first region with respect to an upper surface of the substrate is higher than that of an upper surface of the film in the second region.

According to this application example, since the parallelism of the upper surface of the film in the first region with respect to the upper surface of the substrate is higher than that of the upper surface of the film in the second region, a stable optical signal is provided, whereby satisfactory optical characteristics can be provided.

### APPLICATION EXAMPLE 3

A method for manufacturing an optical part according to this application example includes a preparation step of preparing an optical substrate, a placement step of placing a mask member having a through hole in such a way that the through hole is present on the substrate, that a light blocking portion that extends from an edge of an opening that forms the through hole overlaps with the substrate, and that the distance between the light blocking portion and a film facing surface of the substrate that faces the light blocking portion is greater than 0.1 mm but smaller than or equal to 1 mm, and a film formation step of forming an optical film on the substrate by causing an optical film material to pass through the through hole and adhere to a surface of the substrate that includes the film facing surface.

According to this application example, in which the distance between the mask member and the surface of the substrate is set at a value greater than 0.1 mm but smaller than or equal to 1 mm, what is called a bleeding region where the thickness of the optical film formed on the surface of the substrate gradually changes can be formed at the outer circumferential edge of the optical film, and a region having a specified film thickness where intended optical performance (optical characteristics) is achieved can be provided.

### APPLICATION EXAMPLE 4

It is preferable that the method for manufacturing an optical part according to the application example described above further includes, after the placement step, a cleaning step of cleaning the substrate in a state in which the mask member is placed on the substrate.

### APPLICATION EXAMPLE 5

In the method for manufacturing an optical part according to the application example described above, it is preferable that the cleaning step is carried out at least at one of the time points between the placement step and the film formation step and after the film formation step.

According to this application example, in which the substrate is cleaned in the state in which the mask member is placed on the substrate, attachment and detachment of the substrate is not required, whereby productivity of the optical part can be improved, and adhesion of dust and other types of foreign matter to the substrate can be avoided.

### APPLICATION EXAMPLE 6

An electronic apparatus according to this application example includes the optical part according to the application example described above.

According to this application example, since an optical part in which residual stress, such as stress induced at the time of film formation, is gradually released and intended optical performance (optical characteristics) is ensured is provided, an electronic apparatus capable of stably providing desired characteristics can be provided.

### APPLICATION EXAMPLE 7

A moving object according to this application example includes the optical part according to the application example described above.

According to this application example, since an optical part in which residual stress, such as stress induced at the time of film formation, is gradually released and intended optical performance (optical characteristics) is ensured is provided, a moving object capable of stably providing desired characteristics can be provided.

### BRIEF DESCRIPTION OF THE DRAWINGS

The invention will be described with reference to the accompanying drawings, wherein like numbers reference like elements.

FIGS. 1A to 1C show the configuration of an optical multilayer film filter that is an optical part according to an embodiment of the invention. FIG. 1A is a plan view, FIG. 1B is a cross-sectional view, and FIG. 10 is a partially enlarged view of a portion Q shown in FIG. 1B.

FIG. 2 is a step flowchart associated with optical film formation.

FIG. 3 is an exploded perspective view showing an optical substrate mounting fixture used for the optical film formation.

FIGS. 4A and 4B show a state in which a substrate is mounted on the substrate mounting fixture. FIG. 4A is a cross-sectional view showing an example in which the substrate mounting fixture according to the embodiment is used. FIG. 4B is a cross-sectional view showing an example in which a substrate mounting fixture according to a variation is used.

FIGS. 5A to 5C show the optical multilayer film filter according to the present embodiment. FIG. 5A is a cross-sectional view showing a state in which an optical substrate is mounted on the substrate mounting fixture. FIG. 5B is a plan view of a formed optical multilayer film filter. FIG. 5C is a cross-sectional view of FIG. 5B.

FIGS. 6A and 6B show an optical multilayer film filter formed by using a substrate mounting fixture of related art according to Comparative Example. FIG. 6A is cross-sectional view showing a state in which a substrate is mounted on the substrate mounting fixture. FIG. 6B is a plan view of a formed optical multilayer film filter.

FIG. 7 is a perspective view showing the configuration of a mobile phone as an example of an electronic apparatus.

FIG. 8 is a perspective view showing the configuration of a digital still camera as an example of an electronic apparatus.

FIG. 9 is a perspective view showing the configuration of an automobile as an example of a moving object.

### DESCRIPTION OF EXEMPLARY EMBODIMENTS

### Embodiment

An optical multilayer film filter will be described below in detail as an example of an optical part according to an embodiment of the invention with reference to the drawings. It is, however, noted that the invention is not limited at all to the embodiment. In the description, portions having the same structure and function have the same reference character.

The present embodiment is an example in which the invention is applied to an optical multilayer film filter having an optical characteristic of transmitting light in a visible wavelength band and blocking light in an ultraviolet wavelength band having wavelengths shorter than or equal to a predetermined wavelength and light in an infrared wavelength band having wavelengths longer than or equal to a predetermined wavelength (UV-IR blocking filter). The optical part according to an embodiment of the invention can, for example, instead be an optical lowpass filter, to which the invention is applicable.

### Configuration of Optical Multilayer Film Filter

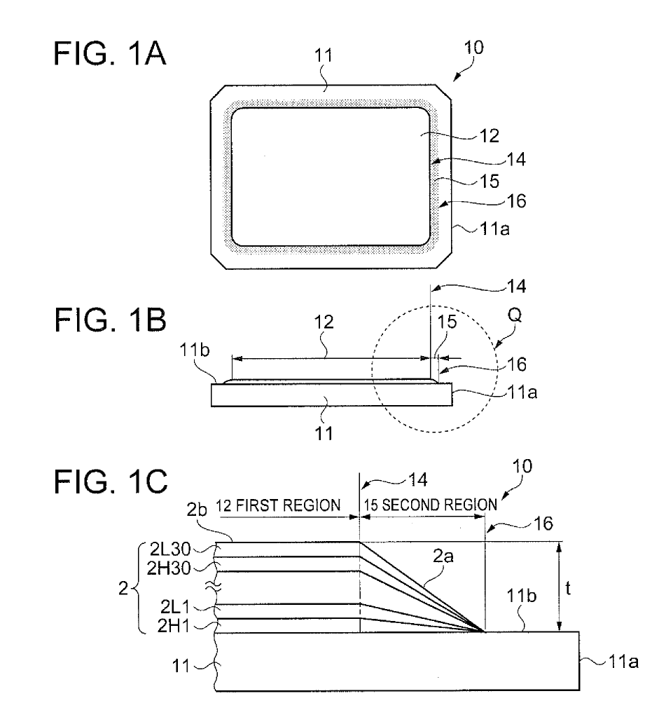

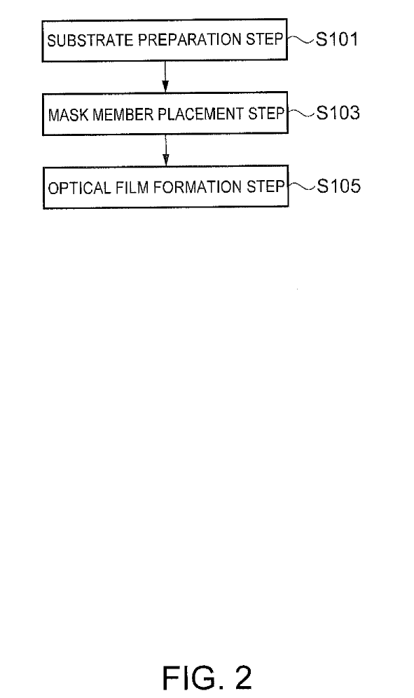

The configuration of the optical multilayer film filter as an example of the optical part will first be described with reference to FIGS. 1A to 2C. FIGS. 1A to 1C diagrammatically show the configuration of the optical multilayer film filter that is the optical part according to an embodiment of the invention. FIG. 1A is a plan view, FIG. 1B is a cross-sectional view of FIG. 1A, and FIG. 1C is a partially enlarged view of a portion Q shown in FIG. 1B.

An optical multilayer film filter 10 includes a glass substrate 11, which serves as an optical substrate that transmits light, and an inorganic thin film 2, which serves as a multilayer film and is disposed on the upper surface of the glass substrate 11. The glass substrate 11 is made of a white glass (refractive index: n=1.52), and a substrate having a roughly rectangular outer shape and a thickness of 0.3 mm is used as the glass substrate 11 in the present embodiment. The optical substrate may be a transparent substrate made, for example, of white glass, BK7, sapphire glass, borosilicate glass, blue glass, SF3, SF7, silicon, or quartz, and a commercially available transparent optical glass substrate may also be used.

The inorganic thin film 2 as the multilayer film is made of TiO₂ (n=2.40), of which high refractive index material layers (H) are made, and SiO₂ (n=1.46), of which low refractive index material layers (L) are made. The inorganic thin film 2 is formed first by placing a TiO₂ film 2H1 made of the high refractive index material TiO₂ from the glass substrate 11 side and then layering an SiO₂ film 2L1 made of the low refractive index material SiO₂ on the upper surface of the TiO₂ film 2H1 made of the high refractive index material TiO₂ and placed as described above. TiO₂ films made of the high refractive index material TiO₂ and SiO₂ films made of the low refractive index material SiO₂ are then sequentially and alternately layered on the upper surface of the SiO₂ film 2L1 made of the low refractive index material SiO₂, and an SiO₂ film 2L30 made of the low refractive index material SiO₂ is layered as the uppermost film layer (outermost layer) of the inorganic thin film 2. The inorganic thin film 2 having 30 high refractive index material layers and 30 low refractive index material layers, 60 layers in total, is thus formed. The description has been made of the case where the high refractive index material layers are made of TiO₂, but the high refractive index material layers may instead be made of Ta₂O₅ or Nb₂O₅.

The film configuration of the inorganic thin film 2 will be described in detail. In the notation of the film thickness configuration described below, each film thickness is expressed in the form of a film thickness nd=1/4λ. Specifically, the film thickness of a high refractive index material layer (H) is expressed as 1H, and the film thickness of a low refractive index material layer (L) is similarly expressed as 1L. Further, notation “S” in (xH, yL)^{S} means the number of repetition called a stack number, and (xH, yL)^{S} means that the configuration in the parentheses is periodically repeated by S.

The film thickness configuration of the inorganic thin film 2 is as follows assuming that a design wavelength λ is 550 nm: The TiO₂ film 2H1 made of the high refractive index material TiO₂, which is first layer, has a thickness of 0.60H; the SiO₂ film 2L1 made of the low refractive index material SiO₂, which is the second layer, has a thickness of 0.20L; sequentially followed by 1.05H; 0.37L; (0.68H, 0.53L)⁴; 0.69H; 0.42L; 0.59H; 1.92L; (1.38H, 1.38L)⁶; 1.48H; 1.52L; 1.65H; 1.71L; 1.54H; 1.59L; 1.42H; 1.58L; 1.51H; 1.72L; 1.84H; 1.80L; 1.67H; 1.77L; (1.87H, 1.87L)⁷; 1.89H; 1.90L; 1.90H; and the SiO₂ film 2L30 made of the low refractive index material SiO₂, which is the outermost layer (outermost surface), has a thickness of 0.96L, 60 layers in total.

The inorganic thin film 2 has a first region 12, which has a roughly rectangular shape and is located in a central portion of the glass substrate 11, and a second region 15, which continuously extends from the first region 12. The second region 15 is so provided that it is located in a portion outside the outer circumferential edge (boundary 14) of the first region 12 and has a frame-like shape (circumferential shape) along the outer circumference of the first region 12.

An upper surface 2b of the inorganic thin film 2 in the first region 12 is formed in parallel to a film facing surface 11b, which is a surface of the glass substrate 11 on which the inorganic thin film 2 is formed. The inorganic thin film 2 in the second region 15 is so formed that the thickness t of the inorganic thin film 2 decreases with distance from the outer circumferential edge (boundary 14) of the first region 12 toward an outer circumferential end 11a of the glass substrate 11, as shown in FIG. 1C. In other words, the thickness t of the inorganic thin film 2 increases with distance from an outer circumferential edge 16 of the second region 15 toward the boundary (intersecting line) 14 between the second region 15 and the first region 12. The same holds true for the films that form the inorganic thin film 2 in the second region 15, specifically, the TiO₂ film 2H1, the SiO₂ film 2L1 to the SiO₂ film 2L30, which is the uppermost layer. That is, the TiO₂ films and the SiO₂ films are so formed that the thicknesses thereof decrease with distance from the outer circumferential edge (boundary 14) of the first region 12 toward the outer circumferential end 11a of the glass substrate 11. A parallelism of the upper surface 2b of the first region 12 with respect to the film facing surface 11b of the glass substrate 11 is higher than that of an upper surface 2a of the second region 15.

As described above, since the inorganic thin film 2 in the second region 15 is so formed that the thickness t thereof decreases with distance from the outer circumferential edge (boundary 14) of the first region 12 toward the outer circumferential end 11a of the glass substrate 11, residual stress in the inorganic thin film 2, such as stress induced when the inorganic thin film 2 is formed, is gradually released. As a result, separation of the inorganic thin film 2 or any other defect due to the residual stress is unlikely to occur, whereby a region having a specified film thickness where intended optical performance (optical characteristics) is achieved can be provided.

Further, the upper surface 2b of the inorganic thin film 2 in the first region 12, whose parallelism with respect to the film facing surface 11b of the glass substrate 11 is higher than that of the upper surface 2a of the inorganic thin film 2 in the second region 15, ensures a stable optical signal, whereby satisfactory optical characteristics of the optical multilayer film filter 10 can be provided.

### Method for Forming Optical Multilayer Film Filter

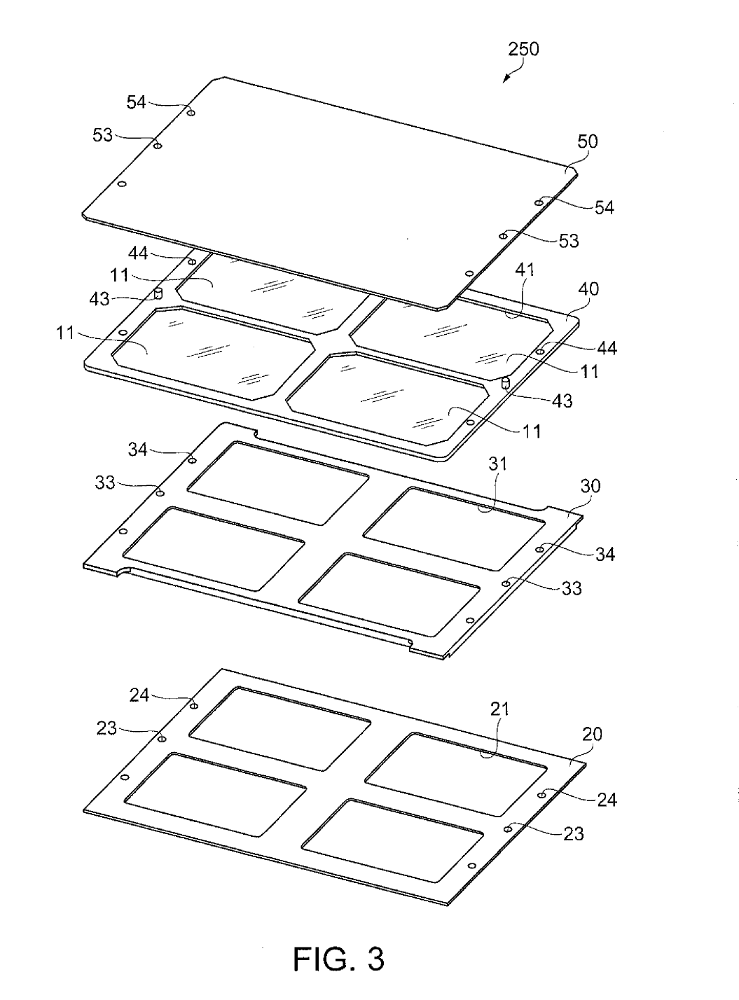

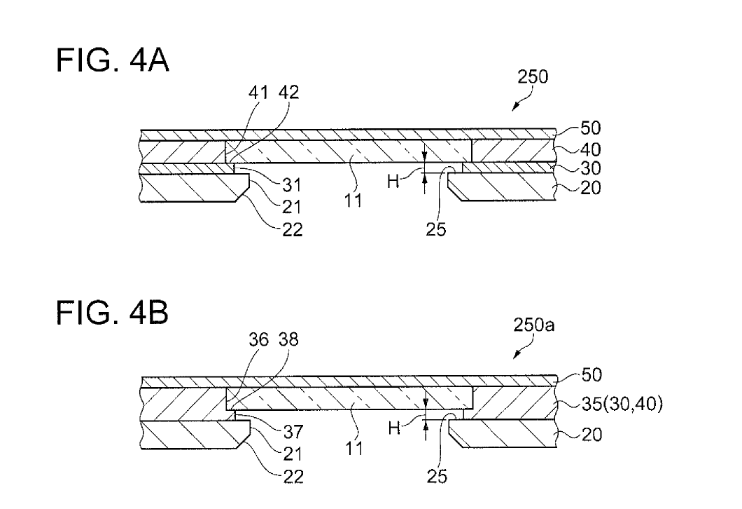

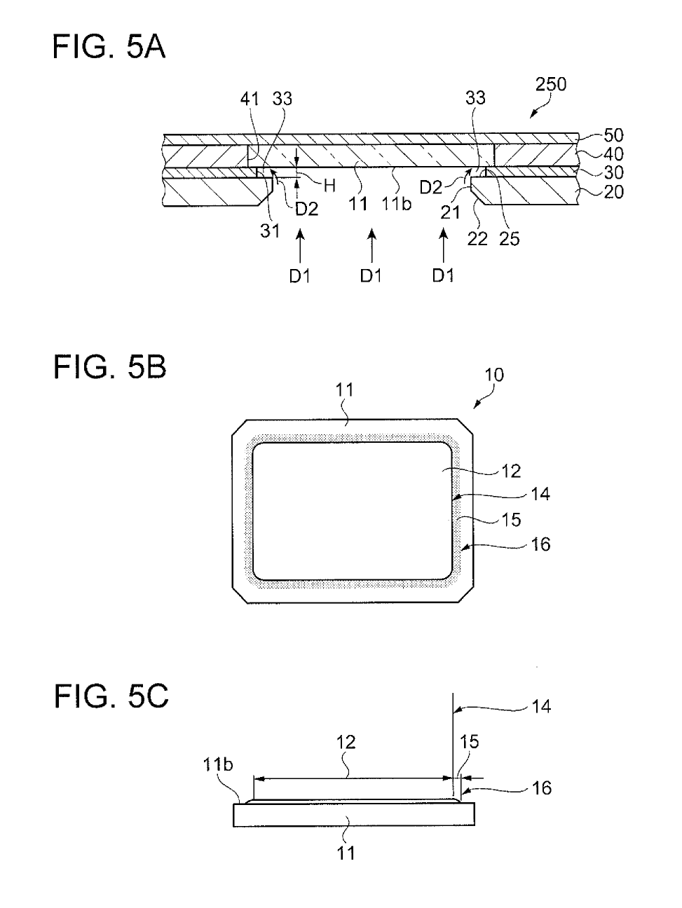

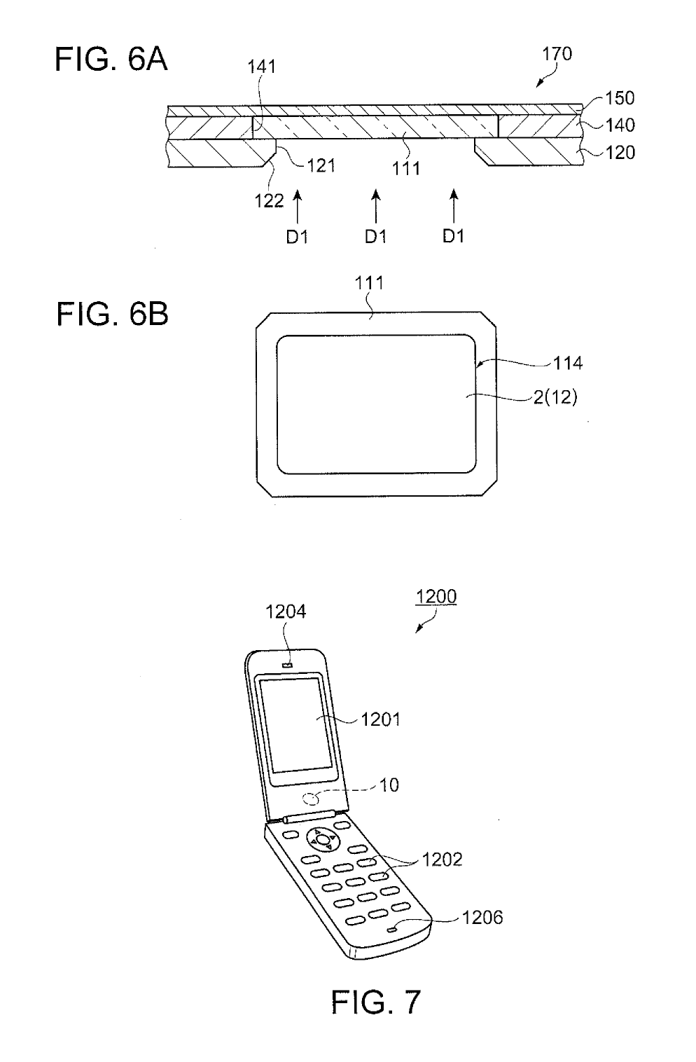

A method for forming the optical multilayer film filter 10 will next be described with reference to FIG. 2 to FIGS. 6A and 6B. FIG. 2 is a step flowchart associated with the method for forming the optical film in the optical multilayer film filter 10. FIG. 3 is an exploded perspective view showing a schematic configuration of an optical substrate mounting fixture used to form the optical film. FIGS. 4A and 4B show a state in which an optical substrate is mounted on the substrate mounting fixture. FIG. 4A is a cross-sectional view showing an example in which the substrate mounting fixture according to the present embodiment is used. FIG. 4B is a cross-sectional view showing an example in which a substrate mounting fixture according to a variation is used. FIGS. 5A to 5C show the optical multilayer film filter according to the present embodiment. FIG. 5A is a cross-sectional view showing a state in which the optical substrate is mounted on the substrate mounting fixture. FIG. 5B is a plan view of a formed optical multilayer film filter. FIG. 5C is a cross-sectional view of FIG. 5B. FIGS. 6A and 6B show an optical multilayer film filter formed by using a substrate mounting fixture of related art as Comparative Example. FIG. 6A is a cross-sectional view showing a state in which a substrate is mounted on the substrate mounting fixture. FIG. 6B is a plan view of a formed optical multilayer film filter.

The method for forming the optical film in the optical multilayer film filter 10 will be described with reference to FIG. 2. In the present embodiment, the optical multilayer film filter 10 is formed in an optical film formation process based on vacuum deposition using a vacuuming apparatus. Steps from a substrate preparation step to an optical film formation step will be sequentially described below.

The glass substrate 11 as the optical substrate that forms a base substrate of the optical multilayer film filter is first prepared (step S101). A white sheet glass (refractive index: n=1.52) having a roughly rectangular outer shape and a thickness of 0.3 mm with chamfered four corners is used as the glass substrate 11. The four corners may not be chamfered.

A mask member placement step, which is a step of mounting the glass substrate 11 on an optical substrate mounting fixture 250 shown in FIG. 3, is then carried out (step S103). The optical substrate mounting fixture 250 used in the mask member placement step (step S103) and a method for mounting the glass substrate 11 on the optical substrate mounting fixture 250 will be described with reference to FIGS. 3 and 4A.

The optical substrate mounting fixture 250 in the present embodiment has a four-layer structure and includes a mask plate 20 as the mask member, a spacer 30, a guide plate 40, and a cover 50, as shown in FIGS. 3 and 4A. The optical substrate mounting fixture 250 functions as a single mounting fixture when the mask plate 20, the spacer 30, the guide plate 40, and the cover 50 are sequentially layered on and fixed to each other. The glass substrate 11 is mounted on the thus configured optical substrate mounting fixture 250.

The guide plate 40 has a function of holding the glass substrate 11. The guide plate 40 is provided with windows 41, on each of which the glass substrate 11 is mounted, at four locations. The glass substrate 11 is mounted in a portion inside each of the windows 41 with the aid of the sidewall of the window 41 that serves as a guide in the planar direction. The guide plate 40 is further provided with guide pins 43, each of which protrudes from the guide plate 40 both toward the front and rear sides, in outer frame portions on opposite sides along one direction (direction along major-axis side of glass substrate 11). Each of the guide pins 43 functions as a positioning pin used when the mask plate 20, the spacer 30, the guide plate 40, and the cover 50 are sequentially layered on each other. The guide plate 40 is still further provided with four fixation holes 44, which pass through the guide plate 40 both toward the front and rear sides, on both sides of the guide pins 43.

The spacer 30 is disposed between the mask plate 20 and the guide plate 40 and used to form a gap H (see FIG. 4A) between the mask plate 20 and the glass substrates 11 so that the mask plate 20 does not directly come into contact with the glass substrates 11. The spacer 30 is provided with windows 31 so located that they face the windows 41 of the guide plate 40 when the spacer 30 is assembled with the guide plate 40. Each of the windows 31 has an inner wall located slightly inside the inner wall of the corresponding window 41 of the guide plate 40. The upper surface of the spacer 30 in a portion from the inner wall of each of the windows 31 to the inner wall of the corresponding window 41 guides the glass substrate 11 in the thickness direction (serve as rear-side stopper). Further, guide holes 33 are provided through outer frame portions on opposite sides of the spacer 30 and in positions facing the guide pins 43 on the guide plate 40, and the guide holes 33 pass through the outer frame portions both toward the front and rear sides. The spacer 30 is further provided with four fixation holes 34, which pass through the spacer 30 both toward the front and rear sides, in positions facing the fixation holes 44 in the guide plate 40.

The mask plate 20 has a function of determining the shape of the inorganic thin film 2 (see FIGS. 1A to 1C) to be formed on each of the glass substrates 11. The mask plate 20 is provided with mask windows 21, each of which is a through hole, so located that they face the windows 41 of the guide plate 40 when the mask plate 20 is assembled with the guide plate 40. The inner wall (opening) of each of the mask windows 21 functions as a mask that determines the outer shape of the inorganic thin film 2, and the inorganic thin film 2 is formed on one surface of the glass substrate 11 when a deposition material that is an optical film material passes through the mask window 21. The mask plate 20 is therefore so disposed that each of the mask windows 21 faces the corresponding glass substrate 11 and a light blocking portion 25, which extends from the inner wall (opening) of the mask window 21, overlaps with the glass substrate 11. The mask plate 20 is further so disposed that the distance between the light blocking portion 25 and the film facing surface 11b of the glass substrate 11, which faces the light blocking portion 25, is greater than 0.1 mm but smaller than or equal to 1 mm. In other words, the inner wall (opening) of each of the mask windows 21 is not only provided in a position where the inner wall coincides with the outer circumferential edge (boundary 14) of the first region 12 of the inorganic thin film 2 in a plan view but also located slightly inside the inner wall of the corresponding window 31 of the spacer 30 (toward center of mask window 21). The inner wall corner of each of the mask windows 21 that faces away from the side where the glass substrate 11 is disposed is chamfered to form a chamfered portion 22. The chamfered portion 22 is provided to allow the deposition material to readily pass through the mask window 21 but is not necessarily provided and may be omitted. Further, guide holes 23 are provided in outer frame portions on opposite sides of the mask plate 20 and in positions facing the guide pins 43 on the guide plate 40, and the guide holes 23 pass through the outer frame portions both toward the front and rear sides. The mask plate 20 is further provided with four fixation holes 24, which pass through the mask plate 20 both toward the front and rear sides, in positions facing the fixation holes 44 in the guide plate 40.

Arranging the mask plate 20 and the glass substrates 11 as described above allows what is called a bleeding region (second region 15, see FIGS. 1A to 1C) where the thickness of the inorganic thin film 2 decreases with distance toward the outer circumferential edge 16 to be effectively formed in an outer circumferential portion of the inorganic thin film 2 as the optical film formed on each of the film facing surfaces 11b. Further, a region having a specified film thickness (first region 12, see FIGS. 1A to 1C) where intended optical performance (optical characteristics) is achieved can be provided.

The cover 50 is so used that it covers the surfaces of the glass substrates 11 mounted on the guide plate 40 that are opposite to the surfaces on which the inorganic thin films 2 are formed to allow no inorganic thin films to be formed on the opposite surfaces. The cover 50 is present on the opposite side of the guide plate 40 to the side where the mask plate 20 is disposed, and the cover 50 is so connected to the guide plate 40 that the cover 50 covers the surfaces of the glass substrates 11 on which no inorganic thin film 2 is formed. The cover 50 is provided with guide holes 53, which pass through the cover 50 both toward the front and rear sides, in positions facing the guide pins 43 on the guide plate 40. The cover 50 is further provided with four fixation holes 54, which pass through the cover 50 both toward the front and rear sides, in positions facing the fixation holes 44 in the guide plate 40.

In the thus configured optical substrate mounting fixture 250, the mask plate 20, the spacer 30, the guide plate 40, and the cover 50 are positioned by the guide pins 43, layered on each other, and then fixed to each other. The fixation can be performed, for example, by using screw fastening or spring fastening, for example, using the fixation holes 24, 34, 44, and 54.

Further, the optical substrate mounting fixture 250 has been described above with reference to the configuration in which the spacer 30 shown in FIG. 4A is used to form the gap H between the mask plate 20 and the glass substrates 11 so that the mask plate 20 does not directly come into contact with the glass substrates 11 but may be configured without the spacer 30. For example, the guide plate 40 and the spacer 30 can be integrated into a single guide plate 35 according to the variation shown in FIG. 4B. The guide plate 35 has guide portions 36, which are so recessed from the surface of the guide plate 35 that the glass substrates 11 are mounted on the guide portions 36, and windows 37, each of which passes through a bottom 38 of the corresponding guide portion 36. When the guide plate 35 is used, the distance from the bottoms 38 to the surface where the guide plate 35 comes into contact with the mask plate 20, that is, the thickness of the windows 37 serves as the gap H between the mask plate 20 and the glass substrates 11.

Referring back to FIG. 2, the optical film formation step (step S105) will be described.

In the optical film formation step (step S105), the inorganic thin film 2 as the optical film is formed on one surface of each of the glass substrates 11. The formation of the inorganic thin film 2 is performed in vacuum deposition in which the glass substrates 11 mounted on the optical substrate mounting fixture 250 in the mask member placement step (step S103) described above is held in a chamber of a vacuuming apparatus. In the present embodiment, typical ion-assisted electron beam deposition (what is called IAD method) is used as the vacuum deposition to form the inorganic thin film 2 on each of the optical glass substrates 11 to manufacture the optical multilayer film filter 10.

Specifically, after the optical substrate mounting fixture 250 on which the glass substrates 11 are mounted is placed in a chamber for the vacuum deposition (not shown), a crucible filled with a deposition material as the optical film material is placed in a lower portion of the chamber, and the deposition material is caused to evaporate by using an electron beam. At the same time, oxygen ionized with an ion gun (Ar is added when TiO₂ film is formed) is accelerated, and each of the glass substrates 11 is irradiated with the accelerated ionized oxygen so that the TiO₂ films 2H1 to 2H30 and the SiO₂ films 2L1 to 2L30 (see FIG. 1C) are alternately formed on the glass substrate 11 in the film configuration described above (see FIG. 1C).

A vacuum pump that is a combination of a dry pump and a turbo molecular pump that are not shown is connected to the chamber of the vacuuming apparatus, and the vacuum pump is activated to exhaust the chamber to provide a predetermined vacuum state. In the vacuum state, the deposition material is deposited on the film facing surfaces 11b of the glass substrates 11 with the glass substrates 11 heated, for example, to about 350°. The vacuum state used in the present description refers to a state of a space having a pressure therein lower than the typical atmospheric pressure (lower than or equal to a value ranging from 1×10⁵ Pa to 1×10⁻¹⁰ Pa (JIS Z 8126-1: 1999)).

The vacuum-deposition-based film formation will be described in detail with reference to FIGS. 5A, 5B, and 5C. As shown in FIG. 5A, the spacer 30 disposed between the mask plate 20 and the guide plate 40 creates the gap H between the glass substrates 11 and the mask plate 20.

A deposition material D1 caused to evaporate and scatter passes through each of the mask windows 21 of the mask plate 20, reaches the glass substrate 11 without being blocked, and forms the inorganic thin film 2 in the first region 12, as shown in FIGS. 5B and 5C. Since the inorganic thin film 2 in the first region 12 is formed with the deposition material D1 having passed through the mask window 21 of the mask plate 20 without being blocked as described above, the formed inorganic thin film 2 has a roughly uniform thickness. In other words, the formed inorganic thin film 2 is highly parallel to the surface of the glass substrate 11 on which the inorganic thin film 2 is formed.

In contrast, outside the first region 12, since the gap H is present between the glass substrate 11 and the mask plate 20, a deposition material D2 travels around and enters the gap H and adheres to the film facing surface 11b of the glass substrate 11. In this case, the deposition material D2 is unlikely to reach a portion far away from the inner wall of the mask window 21, resulting in a decrease in the thickness of the inorganic thin film 2. The deposition material D2 more readily reaches a portion closer to the inner wall of the mask window 21, resulting in an increase in the thickness of the inorganic thin film 2 accordingly. As a result, the second region 15, where the thickness of the inorganic thin film 2 increases with distance from the outer circumferential edge 16 along the inner wall of the window 31 of the spacer 30 toward the boundary (intersecting line) 14 between the second region 15 and the first region 12, is formed.

The inorganic thin film 2 including the first region 12, which has the flat, roughly rectangular upper surface 2b and is provided in a central portion of the glass substrate 11, and the second region 15, in which the thickness of the inorganic thin film 2 increases with distance from the outer circumferential edge 16 to the boundary (intersecting line) 14 between the second region 15 and the first region 12 and which continuously extends from the first region 12, can thus be formed. In other words, the upper surface 2b of the inorganic thin film 2 in the first region 12 is roughly parallel to the film facing surface 11b of the glass substrate 11, and the upper surface 2a of the inorganic thin film 2 in the second region 15 is inclined to the film facing surface 11b of the glass substrate 11.

After the steps described above are carried out, the optical multilayer film filter 10 shown in FIGS. 1A to 1C can be produced.

According to the manufacturing method described above, arranging the mask plate 20 and the glass substrates 11 as described above allows what is called a bleeding region (second region 15) in which the thickness of the inorganic thin film 2 as the optical film formed on the film facing surface lib decreases with distance toward the outer circumference to be effectively formed in an outer circumferential portion of the inorganic thin film 2. The formation of the bleeding region (second region 15) allows residual stress, such as stress induced when the inorganic thin film 2 is formed, to be gradually released. As a result, separation of the inorganic thin film 2 or any other defect due to the residual stress is unlikely to occur, whereby a region having a specified film thickness where intended optical performance (optical characteristics) is achieved can be provided.

Further, a region having a specified film thickness (first region 12) where intended optical performance (optical characteristics) is achieved can be provided.

### COMPARATIVE EXAMPLE

As a comparative example, a case where an optical substrate mounting fixture 170 having a configuration in which no gap H is present between the glass substrates 11 and the mask plate 20 unlike in the embodiment, that is, a configuration in which no spacer 30 described above is used is used will be described with reference to FIGS. 6A and 6B. The optical substrate mounting fixture 170 according to Comparative Example includes a guide plate 140, which has a window 141, on which a glass substrate 111 is mounted, a mask plate 120, which is connected to the guide plate 140 in such a way that the mask plate 120 comes into contact with one surface (surface on which inorganic thin film is formed) of the glass substrate 111, and a cover 150, which covers the other surface of the glass substrate 111 that faces away from the one surface (surface on which inorganic thin film is formed), as shown in FIG. 6A, When the thus configured optical substrate mounting fixture 170 is used to form the inorganic thin film 2 in the vacuum deposition, a deposition material does not travel around, unlike in the embodiment described above, because the glass substrate 111 and the mask plate 120 are in contact with each other. As a result, the deposition material D1 having passed through the mask window 121 of the mask plate 120 forms the inorganic thin film 2, and the inorganic thin film 2 formed in the first region 12 surrounded with an outer circumferential edge 114 has a roughly uniform thickness. That is, the second region 15 in the embodiment described above is not formed.

### Step of Cleaning Glass Substrate

After the mask member placement step (step S103), a cleaning step of cleaning the glass substrates 11 can be carried out in a state in which the mask plate 20 is placed on the glass substrates 11, in other words, in a state in which the glass substrates 11 are mounted on the optical substrate mounting fixture 250. The cleaning step can be carried out at least at one of the following points of time: between the mask member placement step (step S103) and the optical film formation step (step S105); and after the optical film formation step (step S105).

Providing the cleaning step as described above allows the glass substrates 11 to be cleaned in the state in which the mask plate 20 is placed on the glass substrates 11, whereby the attachment and detachment of the glass substrates is not required for improvement in productivity, and adhesion of particles (dust) and other types of foreign matter to the glass substrates 11 is avoided.

Further, in the cleaning step, the cleaning can be performed in the state in which the mask plate 20 is placed on the glass substrates 11, that is, in the state in which the glass substrates 11 are mounted on the optical substrate mounting fixture 250, whereby the attachment and detachment of the glass substrates 11 is not required whenever the cleaning is performed, whereby the cleaning step can be more efficiently performed.

### Electronic Apparatus

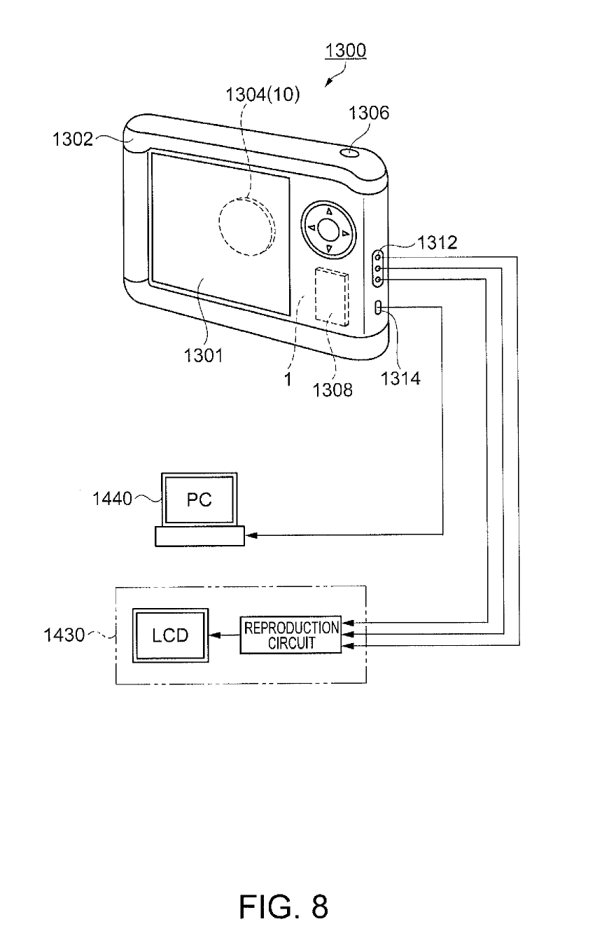

An electronic apparatus using the optical multilayer film filter 10, which is an optical part according to an embodiment of the invention, will next be described with reference to FIGS. 7 and 8.

FIG. 7 is a perspective view schematically showing the configuration of a mobile phone (including PHS) as the electronic apparatus including the optical multilayer film filter 10, which is an optical part according to an embodiment of the invention. In FIG. 7, a mobile phone 1200 includes a plurality of operation buttons 1202, a receiver 1204, and a transmitter 1206, and a display section 1201 is disposed between the operation buttons 1202 and the receiver 1204. The thus configured mobile phone 1200 includes an imaging device that captures an image of a subject, and the optical multilayer film filter 10 is used in the imaging device.

FIG. 8 is a perspective view schematically showing the configuration of a digital still camera as the electronic apparatus including the optical multilayer film filter 10, which is an optical part according to an embodiment of the invention. FIG. 8 also shows connection to an external apparatus in a simplified manner. In a film camera of related art, a silver photographic film is exposed to light, specifically to an optical image of a subject, whereas a digital still camera 1300 converts an optical image of a subject into a captured image signal (image signal) in a photoelectric conversion process by using an imaging device, such as a CCD (charge coupled device). The optical multilayer film filter 10 is used in the imaging device.

A display section 1301 is provided on the rear side of a case (body) 1302 of the digital still camera 1300 and displays an image based on the captured image signal from the CCD. The display section 1301 thus functions as a finder that displays a subject in the form of an electronic image. Further, a light receiving unit 1304, which includes an optical lens (imaging system), the CCD, in which the optical multilayer film filter 10 is used, and other components, is provided on the front side (rear side in FIG. 8) of the case 1302.

When a user of the camera checks a subject image displayed on the display section 1301 and presses a shutter button 1306, a captured image signal from the CCD at that point of time is transferred to and stored in a memory 1308. Further, in the digital still camera 1300, a video signal output terminal 1312 and a data communication input/output terminal 1314 are provided on a side surface of the case 1302. A television monitor 1430 is connected to the video signal output terminal 1312 as necessary, and a personal computer 1440 is connected to the data communication input/output terminal 1314 as necessary, as shown in FIG. 8. Further, in response to predetermined operation, a captured image signal stored in the memory 1308 is outputted to the television monitor 1430 or the personal computer 1440.

The optical multilayer film filter 10 (optical part) according to the embodiment of the invention can be used not only in the mobile phone shown in FIG. 7 and the digital still camera shown in FIG. 8 but also in an electronic apparatus including an imaging device. Examples of the electronic apparatus in which the optical multilayer film filter 10 can be used include a tablet-type information terminal, a handheld personal computer, a television receiver, a video camcorder, a car navigator, a driver recorder, an electronic notepad (including electronic notepad having communication capability), an electronic game console, a TV phone, a security television monitor, electronic binoculars, a medical apparatus, such as an electronic endoscope, and a variety of measuring apparatus.

### Moving Object

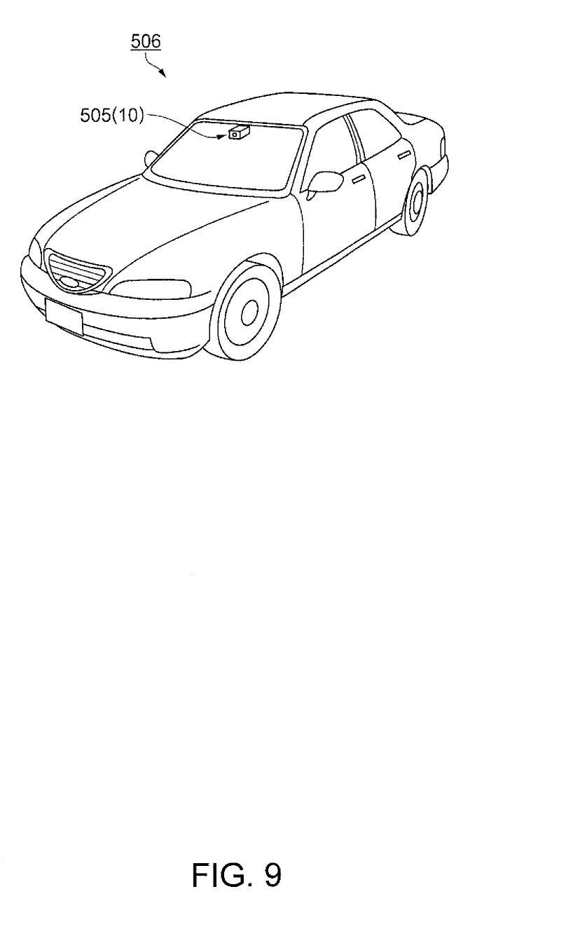

FIG. 9 is a perspective view schematically showing an automobile as an example of a moving object. An automobile 506 accommodates the optical multilayer film filter 10, which is an optical part according to an embodiment of the invention. For example, the automobile 506 as the moving object accommodates a drive recorder 505, which uses an imaging device using the optical multilayer film filter 10 and records running states of the automobile, as shown in FIG. 9. Further, the optical multilayer film filter 10 or any other optical device can be used in other systems, such as a car navigation system, an omnidirectional imaging system (backward monitoring system), a braking system unit, and a vehicle body attitude control system.

The entire disclosure of Japanese Patent Application No. 2014-049807, filed Mar. 13, 2014 is expressly incorporated by reference herein.

What is claimed is:

1. An optical part comprising:
an optical substrate; and
a film provided on the substrate,
wherein the film has a first region and a second region that surrounds the first region and continuously extends from the first region, and
the film in the second region has a thickness that increases with distance from an outer circumferential edge of the second region toward the boundary between the second region and the first region.

2. The optical part according to claim 1,
wherein a parallelism of an upper surface of the film in the first region with respect to an upper surface of the substrate is higher than that of an upper surface of the film in the second region.

3. A method for manufacturing an optical part, the method comprising:
a preparation step of preparing an optical substrate;
a placement step of placing a mask member having a through hole in such a way that the through hole is present on the substrate, that a light blocking portion that extends from an edge of an opening that forms the through hole overlaps with the substrate, and that the distance between the light blocking portion and a film facing surface of the substrate that faces the light blocking portion is greater than 0.1 mm but smaller than or equal to 1 mm; and
a film formation step of forming an optical film on the substrate by causing an optical film material to pass through the through hole and adhere to a surface of the substrate that includes the film facing surface.

4. The method for manufacturing an optical part according to claim 3,
further comprising, after the placement step, a cleaning step of cleaning the substrate in a state in which the mask member is placed on the substrate.

5. The method for manufacturing an optical part according to claim 4,
wherein the cleaning step is carried out at least at one of the time points between the placement step and the film formation step and after the film formation step.

6. An electronic apparatus comprising the optical part according to claim 1.

7. A moving object comprising the optical part according to claim 1.
